(19) United States
(12) Patent Application Publication
(10) Pub. No.: US 2018/0034452 A1
(43) Pub. Date: Feb. 1, 2018

(54) CIRCUIT TECHNIQUE TO TRACK CMOS DEVICE THRESHOLD VARIATION

(71) Applicant: QUALCOMM Incorporated, San Diego, CA (US)

(72) Inventors: Shan Lu, San Diego, CA (US); Nan Chen, San Diego, CA (US); Min Chen, San Marcos, CA (US)

(21) Appl. No.: 15/271,007

(22) Filed: Sep. 20, 2016

Related U.S. Application Data
(60) Provisional application No. 62/366,753, filed on Jul. 26, 2016.

(51) Int. Cl. H03K 5/156; H03K 21/02; H03K 3/03

(52) U.S. Cl. CPC H03K 5/1565; H03K 3/0315; H03K 21/026

(57) ABSTRACT

Methods and systems for independently tracking NMOS device process variation and PMOS device process variation are described herein. In one embodiment, a method for tracking process variation includes measuring a frequency of an NMOS-based ring oscillator on a chip, and determining a threshold voltage or switching speed for NMOS transistors on the chip based on the measured frequency of the NMOS-based ring oscillator. The method also includes measuring a frequency of a PMOS-based ring oscillator on the chip, and determining a threshold voltage or switching speed for PMOS transistors on the chip based on the measured frequency of the PMOS-based ring oscillator.

### RELATED APPLICATION

This application claims priority to U.S. Provisional Application No. 62/366,753 filed on Jul. 26, 2016, the entire specification of which is incorporated herein by reference.

### BACKGROUND

### Field

Aspects of the present disclosure relate generally to tracking process variation, and more particularly, to tracking threshold variation of complementary metal oxide semiconductor (CMOS) devices.

### Background

A chip may include n-type metal oxide semiconductor (NMOS) transistors and p-type metal oxide semiconductor (PMOS) transistors. An NMOS transistor has a threshold voltage, which may be a gate-to-source voltage needed to turn on the NMOS transistor. Similarly, a PMOS transistor has a threshold voltage, which may be a source-to-gate voltage needed to turn on the PMOS transistor. The threshold voltage of a transistor affects the speed with which the transistor can switch in a circuit. Generally, the lower the threshold voltage, the faster the switching speed of the transistor.

### SUMMARY

The following presents a simplified summary of one or more embodiments in order to provide a basic understanding of such embodiments. This summary is not an extensive overview of all contemplated embodiments, and is intended to neither identify key or critical elements of all embodiments nor delineate the scope of any or all embodiments. Its sole purpose is to present some concepts of one or more embodiments in a simplified form as a prelude to the more detailed description that is presented later.

In one aspect, a method for tracking process variation is provided. The method includes measuring a frequency of an NMOS-based ring oscillator on a chip, and determining a threshold voltage or switching speed for NMOS transistors on the chip based on the measured frequency of the NMOS-based ring oscillator. The method also includes measuring a frequency of a PMOS-based ring oscillator on the chip, and determining a threshold voltage or switching speed for PMOS transistors on the chip based on the measured frequency of the PMOS-based ring oscillator.

A second aspect relates to a method for determining a duty cycle setting for a driver on a chip. The method includes counting a number of oscillations of an NMOS-based ring oscillator on the chip over a first period of time to obtain a first count value, counting a number of oscillations of a PMOS-based ring oscillator on the chip over a second period of time to obtain a second count value, and determining the duty cycle setting for the driver on the chip based on the first count value and the second count value.

A third aspect relates to a process-variation tracking system. The system includes an NMOS-based ring oscillator, and a PMOS-based ring oscillator. The system also includes at least one counter configured to count a number of oscillations of the NMOS-based oscillator over a first period of time to obtain a first count value, and to count a number of oscillations of the PMOS-based ring oscillator over a second period of time to obtain a second count value.

To the accomplishment of the foregoing and related ends, the one or more embodiments include the features hereinafter fully described and particularly pointed out in the claims. The following description and the annexed drawings set forth in detail certain illustrative aspects of the one or more embodiments. These aspects are indicative, however, of but a few of the various ways in which the principles of various embodiments may be employed and the described embodiments are intended to include all such aspects and their equivalents.

### BRIEF DESCRIPTION OF THE DRAWINGS

FIG. 1A shows an example of a circuit for tracking CMOS device variation according to certain aspects of the present disclosure.

FIG. 1B shows an example of a CMOS inverter according to certain aspects of the present disclosure.

FIG. 2A shows an example of a circuit for tracking NMOS device variation according to certain aspects of the present disclosure.

FIG. 2B shows an example of an NMOS-based inverter according to certain aspects of the present disclosure.

FIG. 3A shows an example of a circuit for tracking PMOS device variation according to certain aspects of the present disclosure.

FIG. 3B shows an example of a PMOS-based inverter according to certain aspects of the present disclosure.

FIG. 4 shows an exemplary process-variation tracking system according to aspects of the present disclosure.

FIG. 5 shows an example of a system including an adjustable clock source according to certain aspects of the present disclosure.

FIG. 6 shows an example of a system including an adjustable supply voltage source according to certain aspects of the present disclosure.

FIG. 7A shows an example of a driver with an adjustable duty cycle according to certain aspects of the present disclosure.

FIG. 7B shows another example of a driver with an adjustable duty cycle according to certain aspects of the present disclosure.

FIG. 8 shows an example of an NMOS-based oscillator including an output gating circuit according to certain aspects of the present disclosure.

FIG. 9 shows an example of a PMOS-based oscillator including an output gating circuit according to certain aspects of the present disclosure.

FIG. 10 shows another exemplary process-variation tracking system according to certain aspects of the present disclosure.

FIG. 11 is a flowchart showing a method for tracking process variation according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

A chip may include n-type metal oxide semiconductor (NMOS) transistors and p-type metal oxide semiconductor (PMOS) transistors. An NMOS transistor has a threshold voltage, which may be a gate-to-source voltage needed to turn on the NMOS transistor. Similarly, a PMOS transistor has a threshold voltage, which may be a source-to-gate voltage needed to turn on the PMOS transistor. The threshold voltage of a transistor affects the speed with which the transistor can switch in a circuit. Generally, the lower the threshold voltage, the faster the switching speed of the transistor.

The threshold voltages of transistors in a circuit are important because the threshold voltages affect the switching speeds of the transistors, which, in turn, affect the propagation delays of signals in the circuit. The delays need to be within a certain range in order for the circuit to meet certain timing requirements (e.g., setup and hold times) for proper operation.

A challenge is that the threshold voltages of NMOS transistors and PMOS transistors may vary from die to die due to process variation (e.g., variations in fabrication). The amount of process variation becomes particularly pronounced at smaller dimensions (<65 nm). Because the threshold voltages of transistors on a chip affect the timing of circuits on the chip, it is important to measure the threshold voltages of the transistors on the chip.

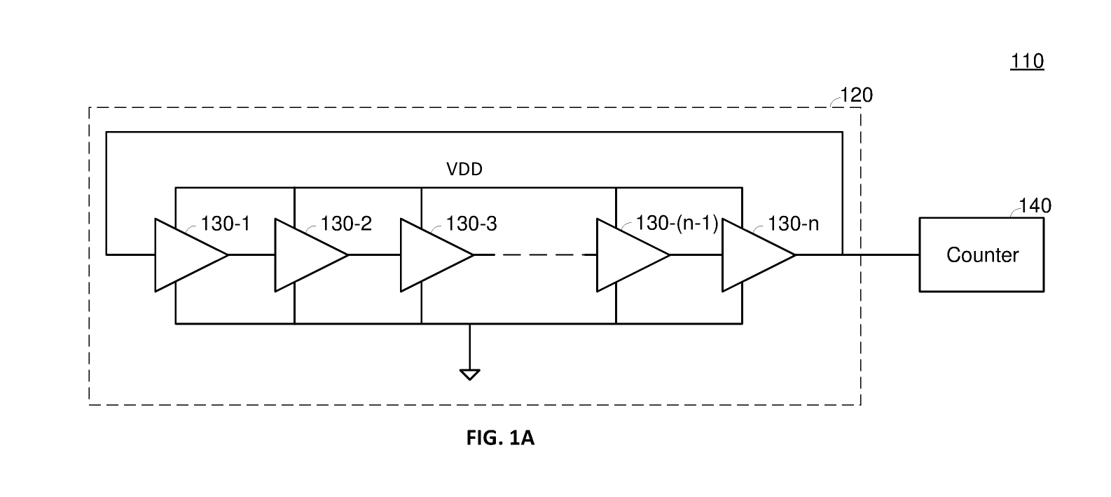

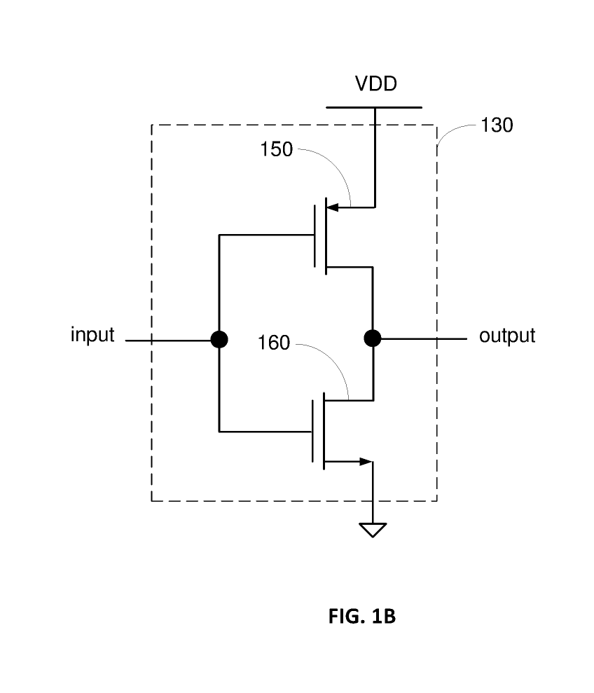

In this regard, FIG. 1A shows an example of an on-chip circuit 110 for measuring threshold voltages on a chip. The circuit 110 includes a ring oscillator 120 and a counter 140. The ring oscillator 120 includes an odd number of inverters 130-1 to 130-n coupled in series, in which the output of the last inverter 130-n is coupled to the input of the first inverter 130-1 to form a ring (closed loop).

Each inverter 130-1 to 130-n is implemented using a complementary inverter (CMOS inverter), an example of which is shown in FIG. 1B. The CMOS inverter 130 includes a PMOS transistor 150 and an NMOS transistor 160. When the input of the inverter 130 is high, the PMOS transistor 150 is turned off and the NMOS transistor 160 is turned on. As a result, the NMOS transistor 160 pulls the output of the inverter 130 low. When the input of the inverter 130 is low, the PMOS transistor 150 is turned on and the NMOS transistor 160 is turned off. As a result, the PMOS transistor 150 pulls the output of the inverter 130 high. Thus, the output of the inverter 130 is the logical inverse of the input of the inverter 130.

The ring oscillator 120 may be referred to as a CMOS ring oscillator 120 since the ring oscillator 120 includes both types of transistors (i.e., PMOS transistors and NMOS transistors).

The frequency of the ring oscillator 120 depends on the delays of the inverters 130-1 to 130-n, which, in turn, depends on the switching speeds (and hence threshold voltages) of the NMOS transistors and PMOS transistors in the inverters. Generally, a faster frequency is indicative of a faster switching speed, and hence a lower threshold voltage. Thus, the frequency of the ring oscillator 120 may be measured, and used to estimate a threshold voltage for the transistors in the ring oscillator 120.

The frequency of the ring oscillator 120 may be measured using a counter 140 coupled to an output of the ring oscillator 120, as shown in FIG. 1A. The counter 140 is configured to measure the frequency of the ring oscillator 120 by counting a number of oscillations at the output of the ring oscillator 120 within a predetermined period of time. The higher the count value, the higher the frequency of the ring oscillator 120.

A drawback of the CMOS ring oscillator 120 is that the frequency of the CMOS ring oscillator 120 depends on the threshold voltages of both the NMOS transistors and the PMOS transistors in the inverters 130-1 to 130-n. As a result, the frequency of the CMOS ring oscillator 120 cannot be used to separately measure the threshold voltage of the NMOS transistors and the threshold voltage of the PMOS transistors. In other words, the CMOS ring oscillator 120 cannot de-couple the effects of process variation on the NMOS transistors and the PMOS transistors.

This is a problem because the threshold voltage of NMOS transistors and the threshold voltage of PMOS transistors may vary differently due to, for example, separate doping steps used for the NMOS transistors and PMOS transistors. As a result, a chip may have fast NMOS transistors and slow PMOS transistors, or slow NMOS transistors and fast PMOS transistors. The circuit 110 in FIG. 1 is not able to distinguish between a chip having fast NMOS transistors and slow PMOS transistors and a chip having slow NMOS transistors and fast PMOS transistors since both may cause the ring oscillator 120 to have a similar output frequency.

Embodiments of the present disclosure provide methods and systems that de-couple the effects of process variation on the threshold voltage of NMOS transistors and the threshold voltage of PMOS transistors. In certain embodiments, an NMOS-based ring oscillator is provided to measure the threshold voltage of NMOS transistors on a chip and a separate PMOS-based ring oscillator is provided to separately measure the threshold voltage of PMOS transistors on the chip, as discussed further below.

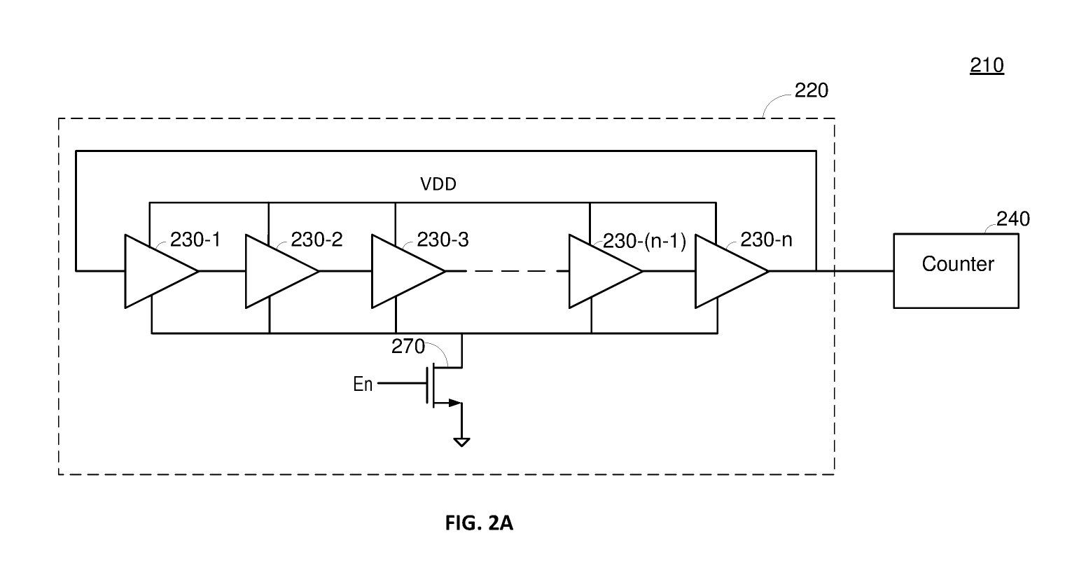

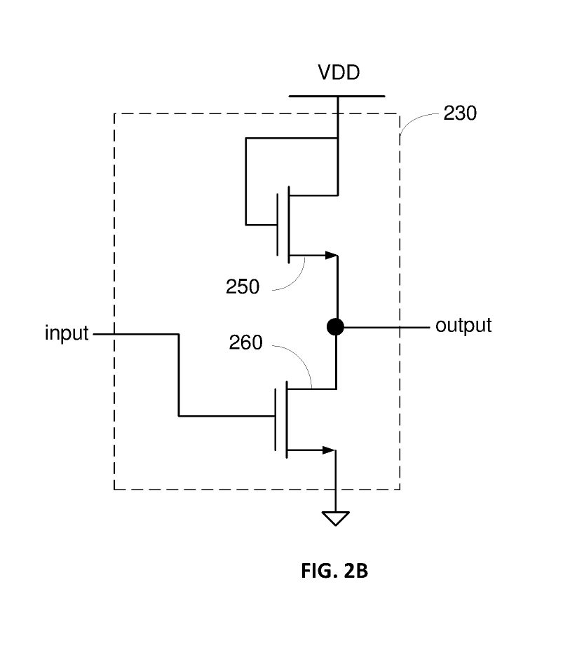

FIG. 2A shows an exemplary circuit 210 for measuring the threshold voltage of NMOS transistors on a chip according to certain aspects of the present disclosure. The circuit 210 includes an NMOS-based ring oscillator 220, and an oscillator counter 240 coupled to an output of the NMOS-based ring oscillator 220. The NMOS-based ring oscillator 220 includes an odd number of inverters 230-1 to 230-n coupled in series, in which the output of the last inverter 230-n is coupled to the input of the first inverter 230-1 to form a ring (closed loop).

In certain aspects, the inverters 230-1 to 230-n only include NMOS transistors so that the delays of the inverters depend only on the threshold voltage of the NMOS transistors. As a result, the frequency of the ring oscillator 220 depends on the threshold voltage of the NMOS transistors, and is therefore indicative of the threshold voltage of the NMOS transistors. Thus, the frequency of the NMOS-based ring oscillator 220 may be measured, and used to estimate the threshold voltage of NMOS transistors on the same chip as the NMOS-based ring oscillator 220, as discussed further below.

FIG. 2B shows an exemplary NMOS-based inverter 230 that can be used to implement each inverter 230-1 to 230-n. The NMOS-based inverter 230 includes a first NMOS transistor 250 and a second NMOS transistor 260. The first NMOS transistor 250 is diode-connected, in which a gate and a drain of the first NMOS transistor 250 are tied together and coupled to the supply rail VDD, as shown in FIG. 2B. A source of the NMOS transistor 250 is coupled to the output of the inverter 230. The second NMOS transistor 260 has a drain coupled to the output of the inverter 230, a gate coupled to the input of the inverter 230, and a source coupled to ground. Because the NMOS-based inverter 230 only includes NMOS transistors, the delay of the inverter 230 is indicative of the threshold voltage of the NMOS transistors.

The oscillator counter 240 is configured to measure the frequency of the NMOS-based ring oscillator 220 by counting a number of oscillations at the output of the ring oscillator within a predetermined period of time. The higher the count value, the higher the frequency of the ring oscillator. For example, the oscillator counter 240 may count oscillations by counting the number of rising edges at the output, the number of falling edges at the output, or the number of both rising and falling edges at the output.

In certain aspects, the NMOS-based ring oscillator 220 also includes a power switch for power gating the NMOS-based ring oscillator 220. In the example in FIG. 2A, the power switch is implemented using an NMOS transistor 270 coupled between the inverters 230-1 to 230-n and ground. More particularly, the NMOS transistor 270 has a drain coupled to the inverters 230-1 to 230-n, a gate that receives an enable signal (denoted “En”), and a source coupled to ground. For the example in which each of the inverters 230-1 to 230-n is implemented using the inverter 230 shown in FIG. 2B, the drain of the NMOS transistor 270 is coupled to the source of the second NMOS transistor 260 of each of the inverters 230-1 to 230-n.

To power the inverters 230-1 to 230-n, the enable signal is asserted high. This turns on the NMOS transistor 270, causing the NMOS transistor 270 to couple the inverters 230-1 to 230-n to ground, allowing current to flow through the inverters. To power down the inverters 230-1 to 230-n, the enable signal is asserted low. This turns off the NMOS transistor 270, causing the NMOS transistor 270 to de-couple the inverters 230-1 to 230-n from ground. This helps prevent current (e.g., static current) from flowing through the inverters when the ring oscillator 220 is not being used, thereby conserving power when the ring oscillator 220 is not being used.

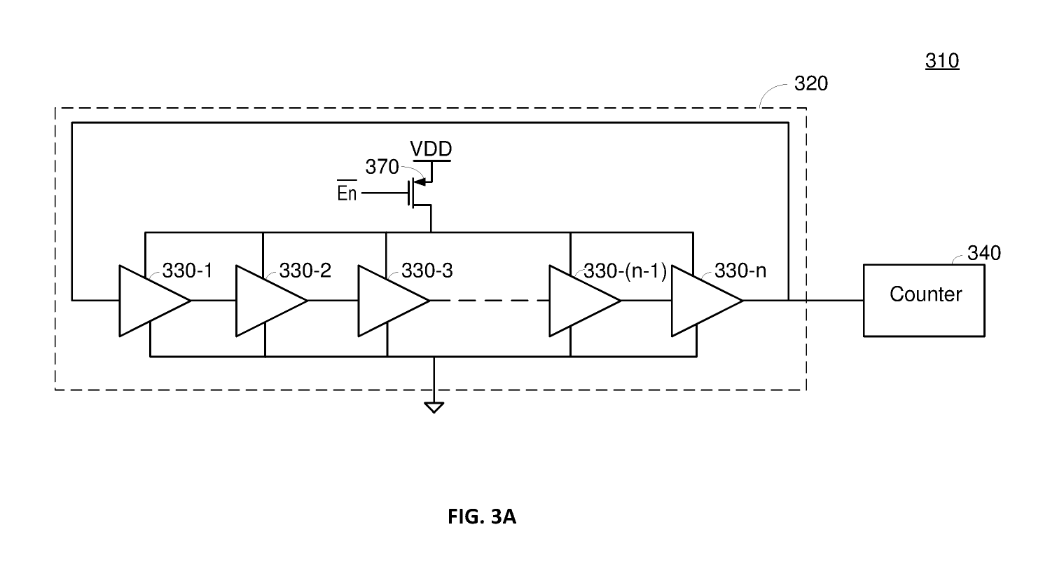

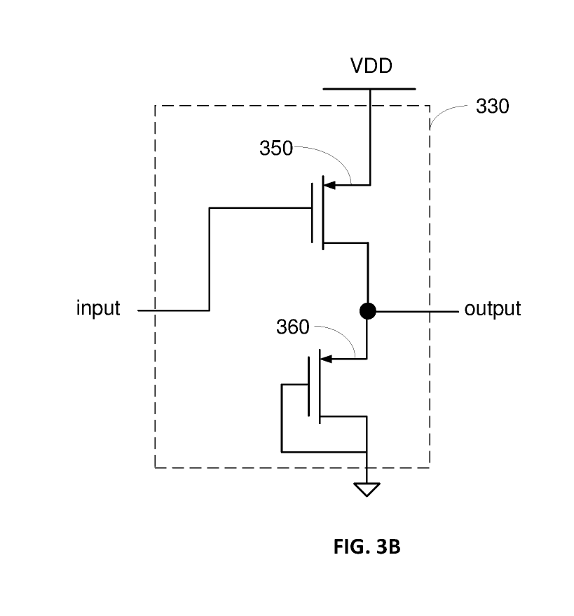

FIG. 3A shows an exemplary circuit 310 for measuring the threshold voltage of PMOS transistors on a chip according to certain aspects of the present disclosure. The circuit 310 includes a PMOS-based ring oscillator 320, and an oscillator counter 340 coupled to an output of the PMOS-based ring oscillator 320. The PMOS-based ring oscillator 320 includes an odd number of inverters 330-1 to 330-n coupled in series, in which the output of the last inverter 330-n is coupled to the input of the first inverter 330-1 to form a ring (closed loop).

In certain aspects, the inverters 330-1 to 330-n only include PMOS transistors so that the delays of the inverters depend only on the threshold voltage of the PMOS transistors. As a result, the frequency of the ring oscillator 320 depends on the threshold voltage of the PMOS transistors, and is therefore indicative of the threshold voltage of the PMOS transistors. Thus, the frequency of the PMOS-based ring oscillator 320 may be measured, and used to estimate the threshold voltage of PMOS transistors on the same chip as the PMOS-based ring oscillator 320, as discussed further below.

FIG. 3B shows an exemplary PMOS-based inverter 330 that can be used to implement each inverter 330-1 to 330-n. The PMOS-based inverter 330 includes a first PMOS transistor 350 and a second PMOS transistor 360. The first PMOS transistor 350 has a source coupled to the supply rail VDD, a gate coupled to the input of the inverter 330, and a drain coupled to the output of the inverter 330. The second PMOS transistor 360 is diode-connected, in which a gate and a drain of the second PMOS transistor 360 are tied together and coupled to ground, as shown in FIG. 3B. A source of the second PMOS transistor 360 is coupled to the output of the inverter 330. Because the PMOS-based inverter 330 only includes PMOS transistors, the delay of the inverter 330 is indicative of the threshold voltage of the PMOS transistors.

The oscillator counter 340 is configured to measure the frequency of the PMOS-based ring oscillator 320 by counting a number of oscillations at the output of the ring oscillator within a predetermined period of time. The higher the count value, the higher the frequency of the ring oscillator. For example, the oscillator counter 340 may count oscillations by counting the number of rising edges at the output, the number of falling edges at the output, or the number of both rising and falling edges at the output. In this example, a rising edge corresponds to a transition from low to high, and a falling edge correspond to a transition from high to low.

In certain aspects, the PMOS-based ring oscillator 320 also includes a power switch for power gating the PMOS-based ring oscillator 320. In the example in FIG. 3A, the power switch is implemented using a PMOS transistor 370 coupled between the supply rail VDD and the inverters 330-1 to 330-n. More particularly, the PMOS transistor 370 has a source coupled to the supply rail VDD, a gate that receives the inverse of the enable signal (denoted “E̅n̅”), and a drain coupled to the inverters 330-1 to 330-n. For the example in which each of the inverters 330-1 to 330-n is implemented using the inverter 330 shown in FIG. 3B, the drain of the PMOS transistor 370 is coupled to the source of the first PMOS transistor 350 of each of the inverters 330-1 to 330-n.

To power the inverters 330-1 to 330-n, the enable signal is asserted high (i.e., the inverted enable signal is asserted low). This turns on the PMOS transistor 370, causing the PMOS transistor 370 to couple the inverters 330-1 to 330-n to the supply rail VDD to power the inverters. To power down the inverters 330-1 to 330-n, the enable signal is asserted low (i.e., the inverted enable signal is asserted high). This turns off the PMOS transistor 370, causing the PMOS transistor 370 to de-couple the supply rail VDD from the inverters 330-1 to 330-n. De-coupling the supply rail VDD from the inverters helps prevent current (e.g., static current) from flowing through the inverters when the ring oscillator 320 is not being used, thereby conserving power when the ring oscillator 320 is not being used.

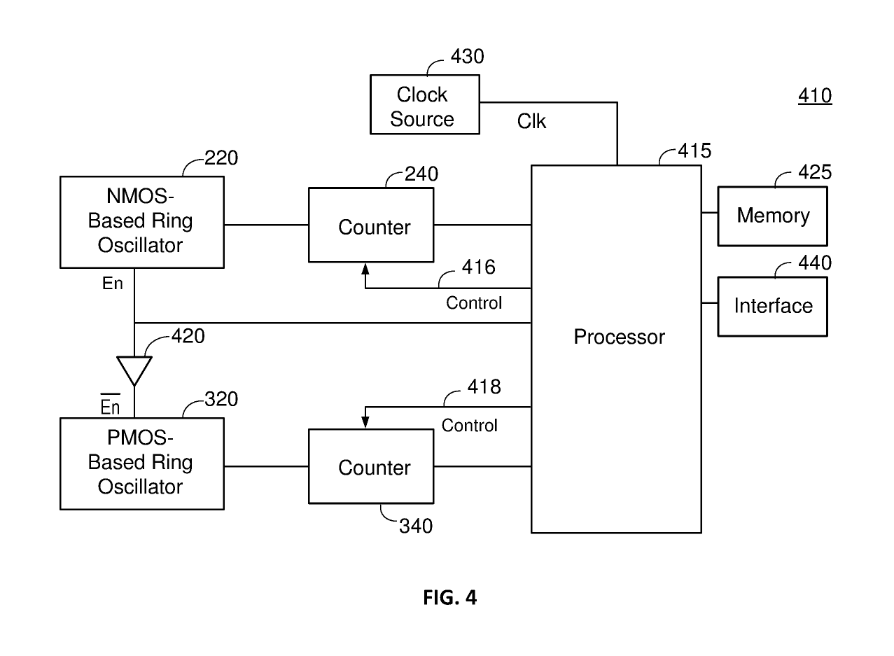

FIG. 4 shows an exemplary on-chip process-variation tracking system 410 according to aspects of the present disclosure. The process-variation tracking system 410 includes the NMOS-based oscillator 220 shown in FIG. 2A and the PMOS-based oscillator 320 shown in FIG. 3A for separately measuring the threshold voltage of NMOS transistors and the threshold voltage of PMOS transistors, respectively. The process-variation tracking system 410 also includes the oscillator counter 240 in FIG. 2A for counting oscillations of the NMOS-based oscillator 220, and the oscillator counter 340 in FIG. 3A for counting oscillations of the PMOS-based oscillator 320.

The system 410 further includes a processor 415 configured to process count values from the oscillator counters 240 and 340. The processor 415 is also configured to selectively enable/disable the oscillators 220 and 320 via the enable signal (denoted “En”). The processor 415 is also configured to control operations of the counters 240 and 340 via control lines 416 and 418, respectively. For example, the processor 415 may be capable of resetting each counter and selectively enabling/disabling each counter, as discussed further below.

To measure the threshold voltage of NMOS transistors, the processor 415 may assert the enable signal (denoted “En”) high. This enables the NMOS-based oscillator 220, as discussed above. The oscillator counter 240 may then count a number of oscillations of the NMOS-based ring oscillator 220 over a predetermined period of time, and output the resulting count value to the processor 415. To do this, the processor 415 may reset the oscillator counter 240, and enable the oscillator counter 240 at the beginning of the predetermined period of time to start the count. The processor 415 may then disable the oscillator counter 240 at the end of the predetermined period of time to stop the count, and read the count value of the oscillator counter 240.

The count value indicates the frequency of the NMOS-based ring oscillator 220, and hence the threshold voltage and switching speed of the NMOS transistors in the oscillator, as discussed above. The processor 415 may store the count value in a memory 425 for later use and/or process the count value, as discussed further below. After the measurement, the processor 415 may disable the NMOS-based oscillator 220 to conserve power by asserting the enable signal low.

To measure the threshold voltage of PMOS transistors, the processor 415 may assert the enable signal (denoted “En”) high. The enable signal is inverted by inverter 420 to obtain an inverted enable signal (denoted “E̅n̅”), which is input to the PMOS-based ring oscillator 320. In this case, the inverted enable signal is low, which enables the PMOS-based ring oscillator 320, as discussed above. The oscillator counter 340 may then count a number of oscillations of the PMOS-based ring oscillator 320 over a predetermined period of time, and output the resulting count value to the processor 415. To do this, the processor 415 may reset the oscillator counter 340, and enable the oscillator counter 340 at the beginning of the predetermined period of time to start the count. The processor 415 may then disable the oscillator counter 340 at the end of the predetermined period of time to stop the count, and read the count value of the oscillator counter 340.

The count value indicates the frequency of the PMOS-based ring oscillator 320, and hence the threshold voltage and switching speed of the PMOS transistors in the oscillator, as discussed above. The processor 415 may store the count value in the memory 425 for later use and/or process the count value, as discussed further below. After the measurement, the processor 415 may disable the PMOS-based oscillator 320 to conserve power by asserting the enable signal low.

As discussed above, the processor 415 may enable an oscillator counter (e.g., oscillator counter 240 or 340) at the beginning of a predetermined period of time to start a count, and disable the oscillator counter at the end of the predetermined period of time to stop the count. To do this, the processor 415 may track the predetermined period of time using a clock signal (denoted “Clk”) from a clock source 430. In one example, the processor 415 may include a clock counter (not shown) driven by the clock signal, in which the predetermined period of time corresponds to a predetermined count value of the clock counter. In this example, the processor 415 may reset the clock counter, and start the clock counter at approximately the same time as the oscillator counter. The processor 415 may then stop the oscillator counter when the count value of the clock counter reaches the predetermined count value indicating the end of the predetermined period of time.

Thus, the process-variation tracking system 410 provides a count value indicating the frequency of the NMOS-based ring oscillator 220, and hence the threshold voltage and switching speed of the NMOS transistors making up the NMOS-based ring oscillator 220. The greater the count value, the higher the frequency of the NMOS-based ring oscillator 220, and hence the lower the threshold voltage of the NMOS transistors and the higher the switching speed of the NMOS transistors. The process-variation tracking system 410 also provides a count value indicating the frequency of the PMOS-based ring oscillator 320, and hence the threshold voltage and switching speed of the PMOS transistors making up the PMOS-based ring oscillator 320. The greater the count value, the higher the frequency of the PMOS-based ring oscillator 320, and hence the lower the threshold voltage of the PMOS transistors and the higher the switching speed of the PMOS transistors. Therefore, the process-variation tacking system 410 is able to independently track NMOS process variation and PMOS process variation.

Information provided by the count values may be used to determine whether circuits on the same chip as the tracking system 410 meet certain timing requirements for proper operation. For example, the count value for the NMOS-based ring oscillator 220 may be used to determine whether circuits on the chip that primarily include NMOS transistors are able to meet certain timing requirements for proper operation (e.g., setup and hold times). For instance, the transistors in these circuits may be made up of 70 percent NMOS transistors to all NMOS transistors.

In this regard, the circuits may require that the threshold voltage of the NMOS transistors be below an upper voltage in order to meet the timing requirements. In this example, a threshold voltage may be determined for NMOS transistors on the chip based on the count value for the NMOS-based ring oscillator 220. If the determined threshold voltage is below the upper voltage, then a determination may be made that the circuits will meet the timing requirements. However, if the determined threshold voltage is above the upper voltage, then a determination may be made that the circuits will not meet the timing requirements. In this case, the chip may be screened out. Alternatively, the clock speed of the circuit may be reduced to relax the timing requirements, as discussed further below.

It is to be appreciated that the threshold voltage requirement discussed above may be given in the form of a minimum switching speed requirement. In this example, the switching speed may be determined for NMOS transistors on the chip based on the count value for the NMOS-based ring oscillator 220. The higher the count value, the higher the frequency of the NMOS-based ring oscillator 220, and hence the higher the switching speed of the NMOS transistors. If the determined switching speed is above the minimum speed, then a determination may be made that the circuits will meet the timing requirements. However, if the determined switching speed is below the minimum speed, then a determination may be made that the circuits will not meet the timing requirements. In this case, the chip may be screened out. Alternatively, the clock speed of the circuit may be reduced to relax the timing requirements, as discussed further below.

In another example, the count value for the PMOS-based ring oscillator 320 may be used to determine whether circuits on the chip that primarily include PMOS transistors are able to meet certain timing requirements for proper operation. For instance, the transistors in these circuits may be made up of 70 percent PMOS transistors to all PMOS transistors.

In this regard, the circuits may require that the threshold voltage of the PMOS transistor be below an upper voltage in order to meet the timing requirements. In this example, a threshold voltage may be determined for PMOS transistors on the chip based on the count value for the PMOS-based ring oscillator 320. If the determined threshold voltage is below the upper voltage, then a determination may be made that the circuits will meet the timing requirements. However, if the determined threshold voltage is above the upper voltage, then a determination may be made that the circuits will not meet the timing requirements. In this case, the chip may be screened out. Alternatively, the clock speed of the circuit may be reduced to relax the timing requirements, as discussed further below.

It is to be appreciated that the threshold requirement discussed above may be given in the form of a minimum switching speed requirement. In this example, the switching speed may be determined for PMOS transistors on the chip based on the count value for the PMOS-based ring oscillator 320. The higher the count value, the higher the frequency of the PMOS-based ring oscillator 320, and hence the higher the switching speed of the PMOS transistors. If the determined switching speed is above the minimum speed, then a determination may be made that the circuits will meet the timing requirements. However, if the determined switching speed is below the minimum speed, then a determination may be made that the circuits will not meet the timing requirements. In this case, the chip may be screened out. Alternatively, the clock speed of the circuit may be reduced to relax the timing requirements, as discussed further below.

Thus, the count values provided by the process-variation tracking system 410 can be used to determine whether circuits that primarily include NMOS transistors (e.g., circuits that are more sensitive to NMOS process variation) are able to meet certain timing requirements, and whether circuits that primarily include PMOS transistors (e.g., circuits that are more sensitive to PMOS process variation) are able to meet certain timing requirements. This may not be possible using conventional process-variation tracking systems, which do not independently track NMOS process variations and PMOS process variations.

In certain aspects, the process-variation tracking system 410 may include an interface 440 for communicating with one or more devices on the chip and/or one or more devices external to the chip. For example, the process-variation tracking system 410 may communicate the count values to a device (e.g., on-chip device or external device) via the interface 440, in which the device may use the count values to determine whether timing requirements are meet, as discussed above. In another example, the processor 415 may determine whether timing requirements are meet based on the count values as discussed above, and communicate this information to a device (e.g., on-chip device or external device) via the interface 440.

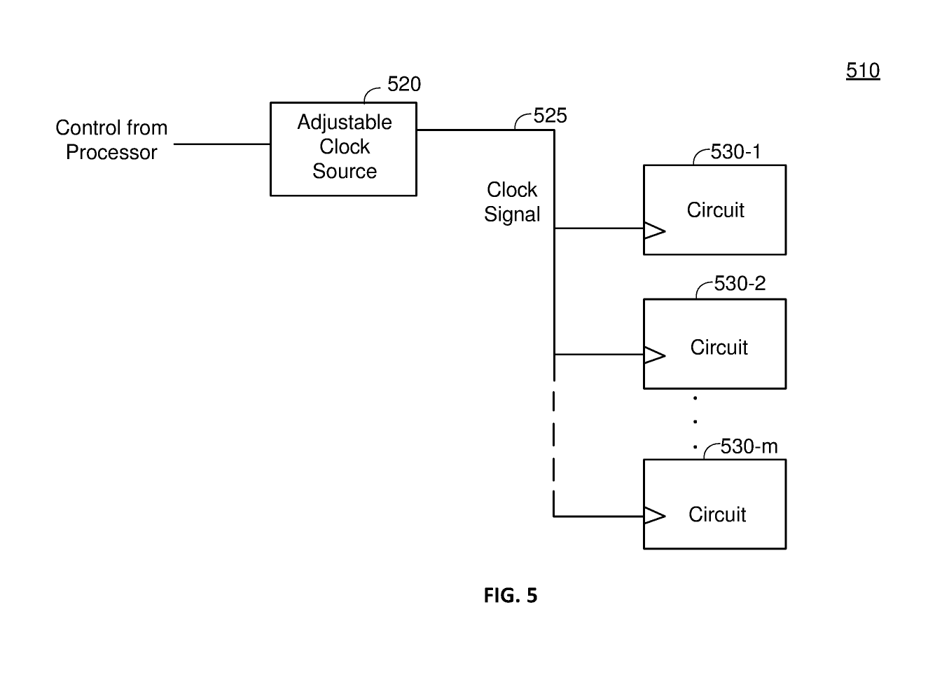

In certain aspects, the processor 415 may be configured to make timing adjustments on the chip based on the count values from the counters 240 and 340. In this regard, FIG. 5 shows a system 510 on the same chip as the tracking system 410 shown in FIG. 4. The system 510 includes an adjustable clock source 520 configured to generate an adjustable clock signal, and multiple circuits 530-1 to 530-m, in which the circuits 530-1 to 530-m receive the clock signal via a clock path 525. The circuits 530-1 to 530-m use the clock signal to time operations in the circuits (e.g., switch transistors in the circuits). The circuits 530-1 to 530-m may include one or more processors (e.g., central processing unit (CPU), graphics processing unit (GPU), etc.), a modem, an audio encoder/decoder, a video encoder/decoder, one or more memory devices, etc. The circuits 530-1 to 530-m may include one or more circuits that primarily include NMOS transistors and/or one or more circuits that primarily include PMOS transistors.

In this example, the processor 415 shown in FIG. 4 may control the frequency of the clock signal output by the adjustable clock source 520 via the interface 440. For example, if the circuits 530-1 to 530-m include one or more circuits that primarily include NMOS transistors, the processor 415 may determine whether these circuits meet certain timing requirements based on the count value for the NMOS transistors, as discussed above. The timing requirements may correspond to a certain frequency of the clock signal. If the processor 415 determines that the timing requirements are not meet, then the processor 415 may instruct the adjustable clock source 520 to reduce the frequency of the clock signal. For example, if the timing requirements corresponds to a first clock frequency, then the processor 415 may instruct the adjustable clock source 520 to set the frequency of the clock signal to a second clock frequency that is lower than the first clock frequency. This may relax the timing requirements of the circuits, making its earlier for the circuits to meet the timing requirements.

In another example, if the circuits 530-1 to 530-m include one or more circuits that primarily include PMOS transistors, the processor 415 may determine whether these circuits meet certain timing requirements based on the count value for the PMOS transistors, as discussed above. The timing requirements may correspond to a certain frequency of the clock signal. If the processor 415 determines that the timing requirements are not meet, then the processor 415 may instruct the adjustable clock source 520 to reduce the frequency of the clock signal. For example, if the timing requirements corresponds to a first clock frequency, then the processor may instruct the adjustable clock source 520 to set the frequency of the clock signal to a second clock frequency that is lower than the first clock frequency. This may relax the timing requirements of the circuits, making its earlier for the circuits to meet the timing requirements.

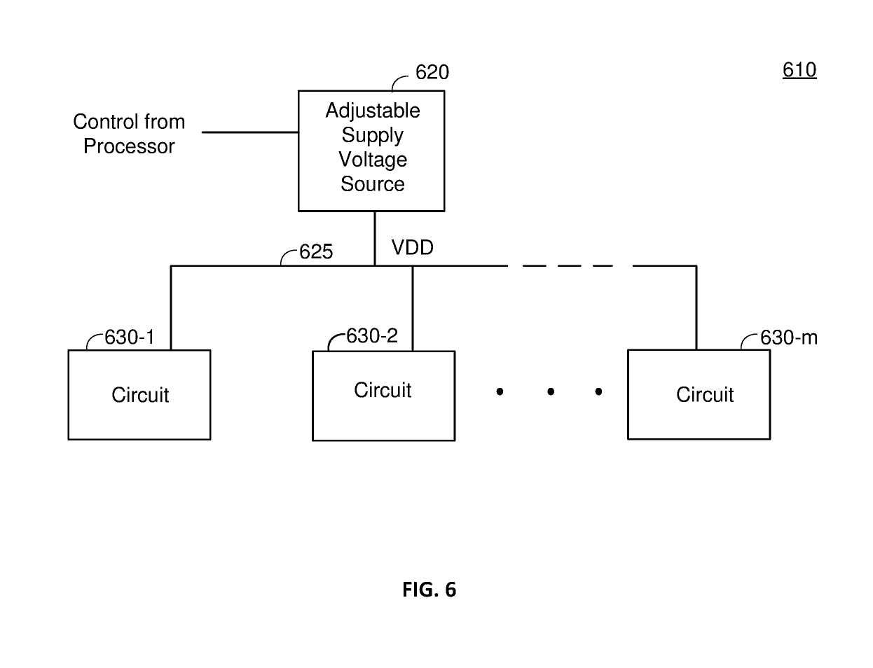

In certain aspects, the processor 415 may be configured to adjust a supply voltage of the chip based on the count values from the counters 240 and 340. In this regard, FIG. 6 shows a system 610 on the same chip as the tracking system 410 shown in FIG. 4. The system 610 includes an adjustable supply voltage source 620 configured to generate an adjustable supply voltage (denoted “VDD”), and multiple circuits 630-1 to 630-m, in which the circuits 630-1 to 630-m are powered by the supply voltage via a power distribution network 625. The circuits 630-1 to 630-m may include one or more processors (e.g., central processing unit (CPU), graphics processing unit (GPU), etc.), a modem, an audio encoder/decoder, a video encoder/decoder, one or more memory devices, etc. The circuits 630-1 to 630-m may include one or more circuits that primarily include NMOS transistors and/or one or more circuits that primarily include PMOS transistors.

In this example, the processor 415 shown in FIG. 4 may control the voltage level of the supply voltage provided by the adjustable voltage source 620 via the interface 440. For example, if the circuits 630-1 to 630-m include one or more circuits that include primarily NMOS transistors, the processor 415 may determine whether these circuits meet certain timing requirements based on the count value for the NMOS transistors, as discussed above. The timing requirements may correspond to a certain voltage level of the supply voltage. If the processor 415 determines that the timing requirements are not meet, then the processor 415 may instruct the adjustable supply voltage source 620 to increase the voltage level of the supply voltage. For example, if the count value was determined at a first supply voltage level (i.e., the ring oscillator 220 was powered at the first supply voltage level), then the processor 415 may instruct the adjustable voltage supply source 620 to set the supply voltage at a second supply voltage level that is higher than the first supply voltage level. The higher supply voltage level may increase the speed of the circuits, allowing the circuits to meet the timing requirements.

In another example, if the circuits 630-1 to 630-m include one or more circuits that primarily include PMOS transistors, the processor 415 may determine whether these circuits meet certain timing requirements based on the count value for the PMOS transistors, as discussed above. The timing requirements may correspond to a certain voltage level of the supply voltage. If the processor 415 determines that the timing requirements are not meet, then the processor 415 may instruct the adjustable supply voltage source 620 to increase the voltage level of the supply voltage. For example, if the count value was determined at a first supply voltage level (i.e., the ring oscillator 320 was powered at the first supply voltage level), then the processor 415 may instruct the adjustable voltage supply source 620 to set the supply voltage at a second supply voltage level that is higher than the first supply voltage level. The higher supply voltage level may increase the speed of the circuits, allowing the circuits to meet the timing requirements.

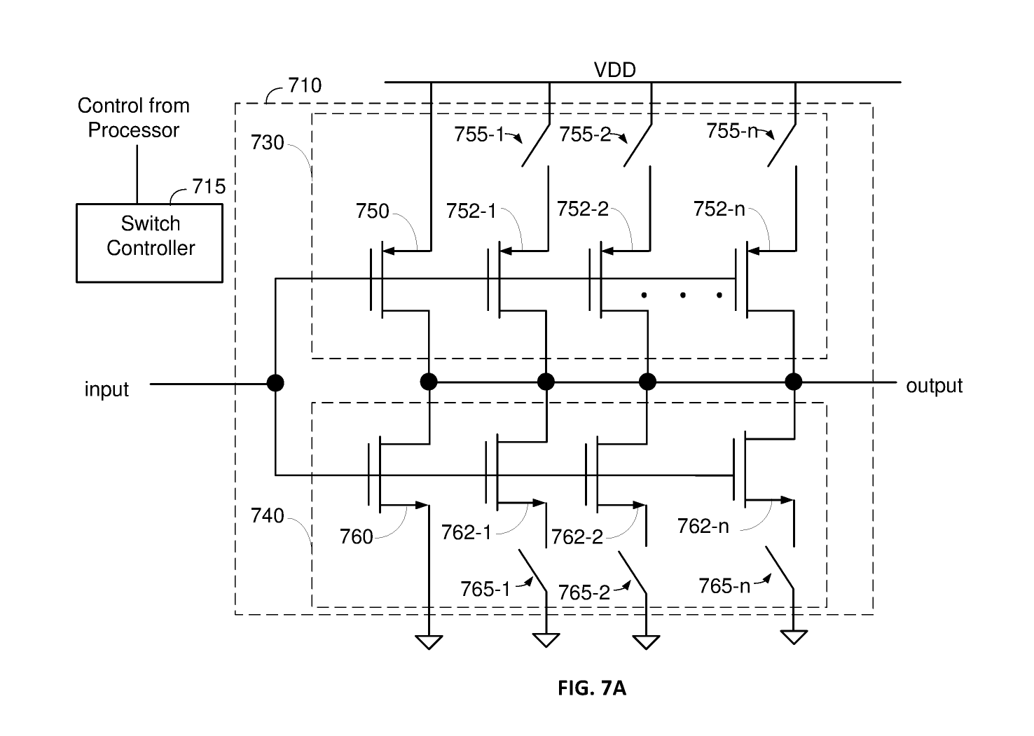

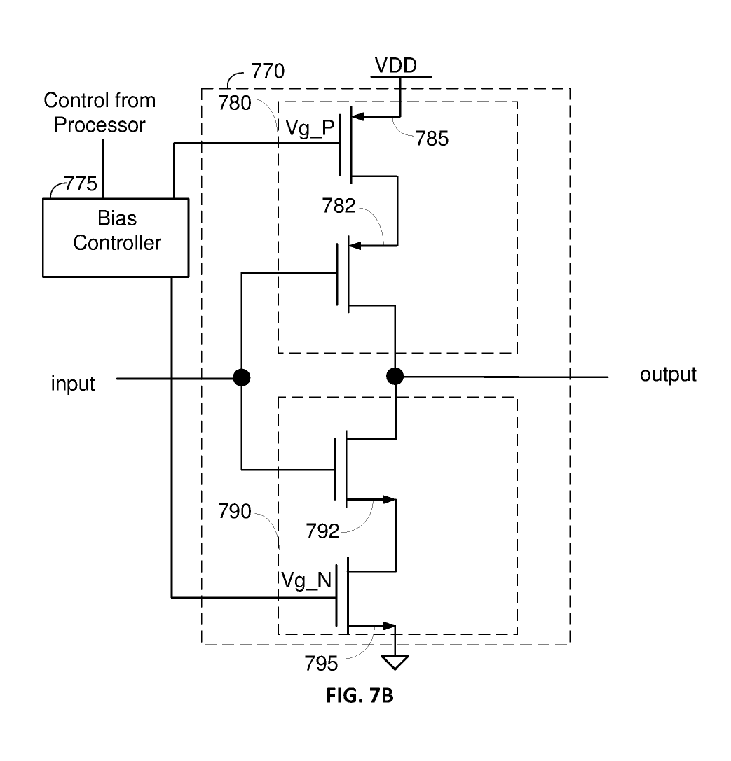

In certain aspects, the processor 415 may be configured to adjust the duty cycle of a driver based on the count values from the counters 240 and 340. In this regard, FIG. 7A shows an example of a driver 710 with an adjustable duty cycle, in which the driver 710 is on the same chip as the tracking system 410 shown in FIG. 4. For example, the driver 710 may receive a clock signal from a clock source (not shown), and output the clock signal to another circuit (not shown). The other circuit may include a memory device, a processor, etc.

In this example, the driver 710 includes a pull-up circuit 730 configured to pull the output high (e.g., to approximately VDD), and a pull-down circuit 740 configured to pull the output low (e.g., to approximately ground). The pull-up circuit 730 includes a PMOS transistor 750 coupled between the supply rail VDD and the output of the driver 710. The pull-up circuit 730 also includes multiple switches 755-1 to 755-n and multiple PMOS transistors 752-1 to 752-n, in which each switch is coupled in series with a respective one of the PMOS transistors 752-1 to 752-n. Each switch-transistor pair is coupled between the supply rail VDD and the output, as shown in FIG. 7A. The gates of the PMOS transistors 750 and 752-1 to 752-n are coupled to the input of the driver 710, as shown in FIG. 7A. The switches 755-1 to 755-n are controlled by a switch controller 715, as discussed further below. For ease of illustration, the individual connections between the switch controller 715 and the switches are not explicitly shown in FIG. 7A.

The pull-down circuit 740 includes an NMOS transistor 760 coupled between the output of the driver 710 and ground. The pull-down circuit 740 also includes multiple switches 765-1 to 765-n and multiple NMOS transistors 762-1 to 762-n, in which each switch is coupled in series with a respective one of the NMOS transistors 762-1 to 762-n. Each switch-transistor pair is coupled between the output and ground, as shown in FIG. 7A. The gates of the NMOS transistors 760 and 762-1 to 762-n are coupled to the input of the driver 710, as shown in FIG. 7A. The switches 765-1 to 765-n are controlled by the switch controller 715, as discussed further below. For ease of illustration, the individual connections between the switch controller 715 and the switches are not explicitly shown in FIG. 7A.

In the example shown in FIG. 7A, the pull-up circuit 730 pulls the output of the driver 710 high (e.g., approximately to VDD) when the input of the driver 710 is low (e.g., approximately ground), and the pull-down circuit 740 pulls the output of the driver 710 low (e.g., approximately to ground) when the input of the driver 710 is high (e.g., approximately VDD). However, it is to be appreciated that the driver 710 is not limited to this example.

To reduce duty cycle distortion caused by the driver 710, it is desirable for the driver 710 to have a rise time and a fall time that are approximately balanced (approximately equal). The rise time depends on the ability of the pull-up circuit 730 to pull up the output of the driver 710. Since the pull-up circuit 730 includes PMOS transistors, the strength of the pull-up circuit 730, and hence the rise time of the driver, depends on the threshold voltage of the PMOS transistors. The lower the threshold voltage of the PMOS transistors, the stronger the pull-up circuit 730. Similarly, the fall time depends on the ability of the pull-down circuit 740 to pull down the output of the driver 710. Since the pull-down circuit 740 includes NMOS transistors, the strength of the pull-down circuit 740, and hence the fall time of the driver, depends on the threshold voltage of the NMOS transistors. The lower the threshold voltage of the NMOS transistors, the stronger the pull-down circuit 740.

Thus, if the threshold voltages of the PMOS transistors and NMOS transistors are skewed (different), the driver 710 may have unbalanced (unequal) rise and fall times, causing duty cycle distortion in the signal (e.g., clock signal) passing though the driver. In this regard, the strengths of the pull-up circuit 730 and pull-down circuit 740 may be adjusted to compensate for skew in the threshold voltages of the PMOS transistors and NMOS transistors, as discussed further below.

The strength of the pull-up circuit 730 is adjusted by selectively opening/closing the switches 755-1 to 755-n. For example, the strength of the pull-up circuit 730 may be increased by closing a larger number of the switches 755-1 to 755-n. This is because closing more of the switches 755-1 to 755-n increases the number of the PMOS transistors 752-1 to 752-n that are used to pull up the output of the driver 710. The strength of the pull-up circuit 730 may be decreased by opening a larger number of the switches 755-1 to 755-n.

Similarly, the strength of the pull-down circuit 740 is adjusted by selectively opening/closing the switches 765-1 to 765-n. For example, the strength of the pull-down circuit 740 may be increased by closing a larger number of the switches 765-1 to 765-n. This is because closing more of the switches 765-1 to 765-n increases the number of the NMOS transistors 762-1 to 762-n that are used to pull down the output of the driver 710. The strength of the pull-down circuit 740 may be decreased by opening a larger number of the switches 765-1 to 765-n.

In certain aspects, the processor 415 may adjust the strength of the pull-up circuit 730 and/or pull-down circuit 740 based on the count values from the counters 240 and 340. For example, if the processor 415 determines that the threshold voltage of the PMOS transistors is lower than the threshold voltage of the NMOS transistor and/or the switching speed of the PMOS transistors is faster than the switching speed of the NMOS transistors, then the processor 415 may instruct the switch controller 715 to increase the strength of the pull-down circuit 740 to compensate for the skew. The switch controller 715 may do this by closing one or more of the switches in the pull-down circuit 740.

For example, all of switches in the pull-up circuit 730 and the pull-down circuit 740 may be initially opened. In this example, the switch controller 715 may strengthen the pull-down circuit 740 by closing one or more of the switches in the pull-down circuit 740. The number of switches that are closed may depend on the difference in the threshold voltages and/or speeds of the NMOS and PMOS transistors. The larger the difference, the larger the number of switches that are closed.

If the processor 415 determines that the threshold voltage of the NMOS transistors is lower than the threshold voltage of the PMOS transistor and/or the switching speed of the NMOS transistors is faster than the switching speed of the PMOS transistors, then the processor 415 may instruct the switch controller 715 to increase the strength of the pull-up circuit 730 to compensate for the skew. The switch controller 715 may do this by closing one or more of the switches in the pull-up circuit 730.

For example, all of switches in the pull-up circuit 730 and the pull-down circuit 740 may be initially opened. In this example the switch controller 715 may strengthen the pull-up circuit 730 by closing one or more of the switches in the pull-up circuit 730. The number of switches that are closed may depend on the difference in the threshold voltages and/or speeds of the NMOS and PMOS transistors. The larger the difference, the larger the number of switches that are closed.

FIG. 7B shows another example of a driver 770 with an adjustable duty cycle. In this example, the driver 770 includes a pull-up circuit 780 configured to pull the output high (e.g., to approximately VDD), a pull-down circuit 790 configured to pull the output low (e.g., to approximately ground), and a gate bias controller 775. The pull-up circuit 780 includes a PMOS transistor 782 and a current-starving PMOS transistor 785 coupled in series between the supply rail VDD and the output of the driver 770. The pull-down circuit 790 includes an NMOS transistor 792 and a current-starving NMOS transistor 795 coupled in series between the output of the driver 770 and ground.

The gates of PMOS transistor 782 and NMOS transistor 792 are coupled to the input of the driver 770. The gate bias voltage of the current-starving PMOS transistor 785 (denoted “Vg_P”) and the gate bias voltage of the current-starving NMOS transistor 795 (denoted “Vg_N”) are controlled by the bias controller 775, as discussed further below.

The strength of the pull-up circuit 780 is adjusted by adjusting the gate bias voltage of the current-starving PMOS transistor 785. For example, the strength of the pull-up circuit 780 may be increased by decreasing the gate bias voltage of the current-starving PMOS transistor 785. This is because decreasing the gate bias voltage increases the channel conductance of the current-starving PMOS transistor 785. The strength of the pull-up circuit 780 may be decreased by increasing the gate bias voltage of the current-starving PMOS transistor 785.

The strength of the pull-down circuit 790 is adjusted by adjusting the gate bias voltage of the current-starving NMOS transistor 795. For example, the strength of the pull-down circuit 790 may be increased by increasing the gate bias voltage of the current-starving NMOS transistor 795. This is because increasing the gate bias voltage increases the channel conductance of the current-starving NMOS transistor 795. The strength of the pull-up circuit 790 may be decreased by decreasing the gate bias voltage of the current-starving NMOS transistor 795.

In certain aspects, the processor 415 may adjust the strength of the pull-up circuit 780 and/or pull-down circuit 790 based on the count values from the counters 240 and 340. For example, if the processor 415 determines that the threshold voltage of the PMOS transistors is lower than the threshold voltage of the NMOS transistor and/or the switching speed of the PMOS transistors is faster than the switching speed of the NMOS transistors, then the processor 415 may instruct the bias controller 775 to increase the strength of the pull-down circuit 790 to compensate for the skew. The bias controller 775 may do this by increasing the gate bias voltage of the current-starving NMOS transistor 795 (e.g., from an initial or default gate bias voltage), as discussed above.

If the processor 415 determines that the threshold voltage of the NMOS transistors is lower than the threshold voltage of the PMOS transistor and/or the switching speed of the NMOS transistors is faster than the switching speed of the PMOS transistors, then the processor 415 may instruct the bias controller 775 to increase the strength of the pull-up circuit 780 to compensate for the skew. The bias controller 775 may do this by decreasing the gate bias voltage of the current-starving PMOS transistor 785 (e.g., from an initial or default gate bias voltage), as discussed above.

In certain aspects, the bias controller 775 may be configured to set the bias voltage of the current-starving PMOS transistor 785 to one of a first set of discrete bias voltages, and to set the bias voltage of the current-starving NMOS transistor 795 to one of a second set of discrete bias voltages. Thus, in these aspects, the bias controller 775 adjusts the gate bias voltages in steps.

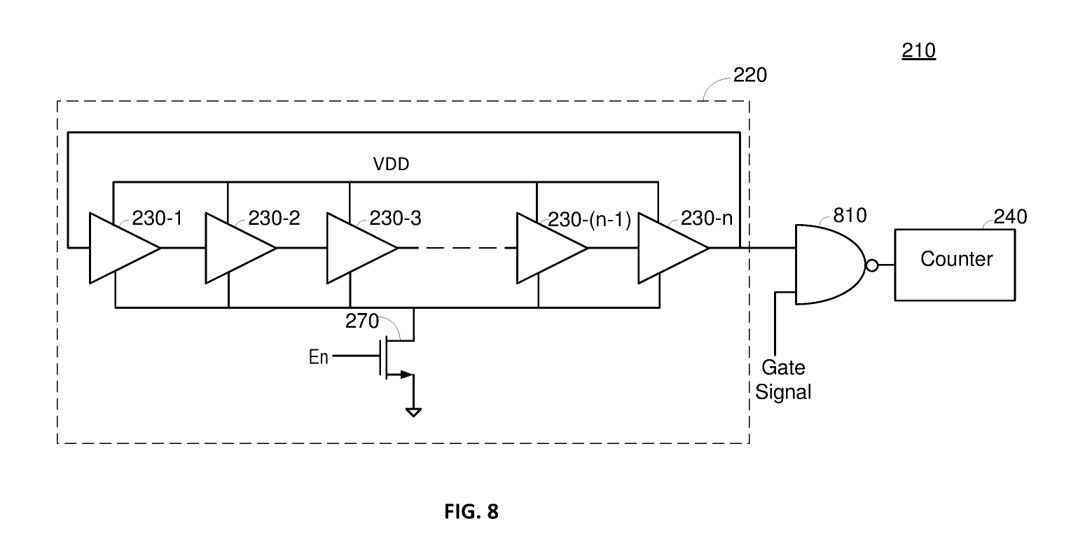

In certain aspects, the output of the NMOS-based oscillator 220 may be gated when the oscillator is disabled. In this regard, FIG. 8 shows an example of a gating circuit 810 coupled between the output of the oscillator 220 and the counter 240. In this example, the gating circuit 810 is implemented with a NAND gate 810 having a first input coupled to the output of the oscillator 220, a second input configured to receive a gate signal, and an output coupled to the counter 240. The logic state of the gate signal controls whether the gating circuit 810 gates the output of the oscillator 220. In this example, when the gate signal is logic one, the NAND gate 810 passes the inverse of the output signal of the oscillator 220 to the counter 240. When that gate signal is logic zero, the output of the NAND gate 810 is held at logic one regardless of the logic state of the oscillator output. Thus, in this example, the NAND gate 810 gates the oscillator output when the gate signal is logic zero.

In certain aspects, the processor 415 may control the gate signal, in which the processor 415 un-gates the oscillator output when the oscillator 220 is enabled, and gates the oscillator output when the oscillator 220 disabled. In the example in which the gating circuit is implemented with a NAND gate, the processor asserts the gate signal high to un-gate the oscillator output, and asserts the gate signal low to gate the oscillator output. In this example, the enable signal may also be used for the gate signal.

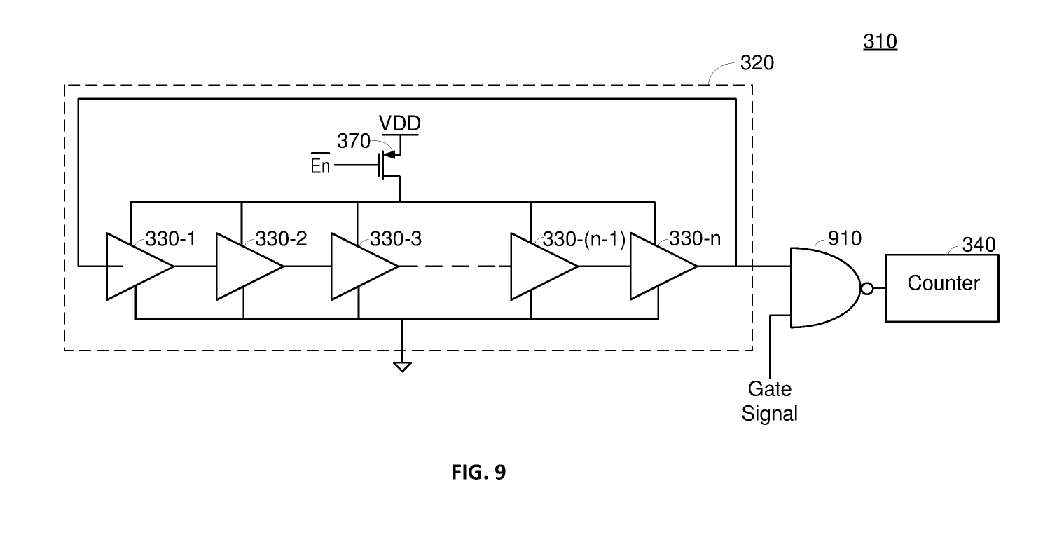

FIG. 9 shows an example of a gating circuit 910 coupled between the output of the PMOS-based oscillator 320 and the counter 340. In this example, the gating circuit 910 is implemented with a NAND gate 910 having a first input coupled to the output of the oscillator 320, a second input configured to receive a gate signal, and an output coupled to the counter 340. The logic state of the gate signal controls whether the gating circuit 910 gates the output of the oscillator 320. In this example, when the gate signal is logic one, the NAND gate 910 passes the inverse of the output signal of the oscillator 320 to the counter 340. When that gate signal is logic zero, the NAND gate 910 gates the oscillator output.

In certain aspects, the processor 415 may control the gate signal, in which the processor 415 un-gates the oscillator output when the oscillator 320 is enabled, and gates the oscillator output when the oscillator 320 disabled. In the example in which the gating circuit is implemented with a NAND gate, the processor asserts the gate signal high to un-gate the oscillator output, and asserts the gate signal low to gate the oscillator output. In this example, the enable signal may also be used for the gate signal.

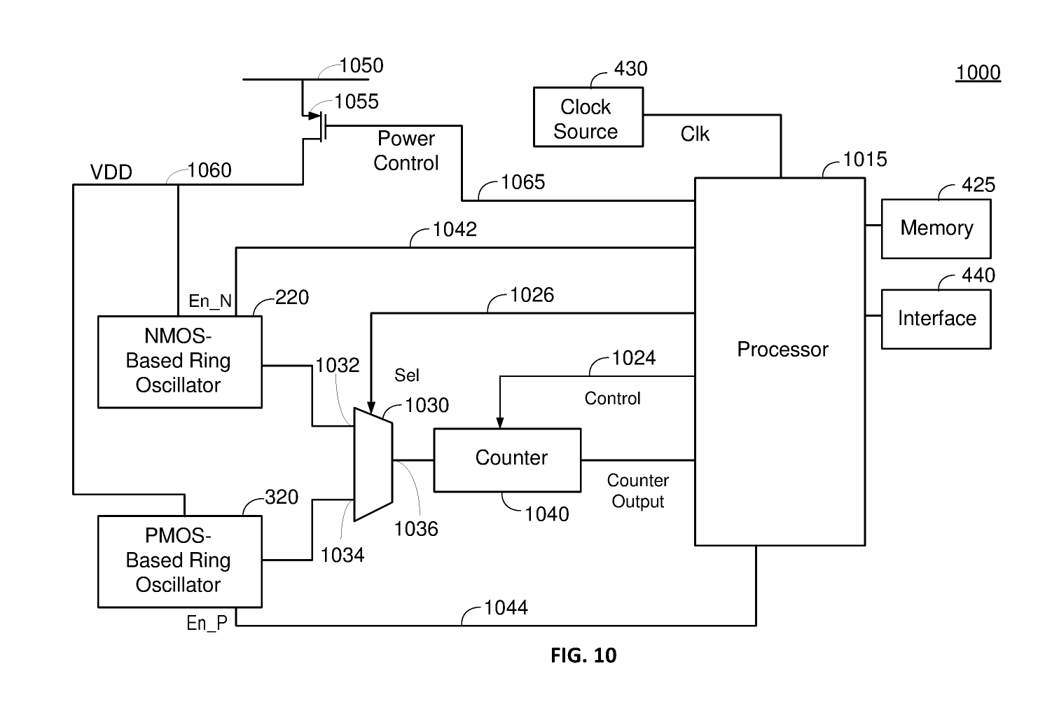

FIG. 10 shows another exemplary on-chip process-variation tracking system 1000 according to certain aspects of the present disclosure. The process-variation tracking system 1000 includes the NMOS-based oscillator 220 shown in FIG. 2A and the PMOS-based oscillator 320 shown in FIG. 3A. The process-variation tracking system 1000 also includes a multiplexer 1030, an oscillator counter 1040, and a processor 1015.

The multiplexer 1036 has a first input 1032 coupled to the output of the NMOS-based oscillator 220, a second input 1034 coupled to the output of the PMOS-based oscillator 320, and an output 1036 coupled to the counter 1040. The multiplexer 1030 is configured to select one of the oscillators 220 and 320 according to a select signal (denoted “Sel”) from the processor 1015, and couple the output of the selected oscillator to the counter 1040. The counter 1040 is configured to convert the frequency of the selected oscillator to a count value, and output the count value to the processor 1015. The counter 1040 may be implemented using a Gray code counter, or another type of counter.

The processor 1015 may be configured to output separate enable signals to the oscillators 220 and 320 to independently enable the oscillators 220 and 320. For example, the processor 1015 may output a first enable signal (denoted “En_N”) to selectively enable/disable the NMOS-based oscillator 220, and a second enable signal (denoted “En_P”) to selectively enable/disable the PMOS-based oscillator 320. The first enable signal En_N may be output to the gate of NMOS transistor 270 (shown in FIG. 2A) via line 1042, and the second enable signal En_P may be output to the gate of PMOS transistor 370 (shown in FIG. 3A) via line 1044. In this example, the processor 1015 may assert the first enable signal En_N high to enable the NMOS-based oscillator 220, and assert the first enable signal En_N low to disable the NMOS-based oscillator 220. The processor 1015 may assert the second enable signal En_P low to enable the PMOS-based oscillator 320, and assert the second enable signal En_P high to disable the PMOS-based oscillator 320. Alternatively, the processor 1015 may enable/disable the oscillators collectively using one enable signal (e.g., enable signal En shown in FIG. 4).

In some embodiments, the processor 1015 is also configured to control operations of the counter 1040 via control line 1024, as discussed further below. The processor 1015 is further configured to output the select signal Sel to the multiplexer 1030 via select line 1026 to selectively couple the output of one of the oscillators 220 and 320 to the counter 1040.

To measure the threshold voltage of NMOS transistors, the processor 1015 may assert the first enable signal En_N high to enable the NMOS-based oscillator 220. The processor 1015 may also command the multiplexer 1030 to couple the output of the NMOS-based oscillator 220 to the counter 1040 using the select signal Sel. The counter 1040 may then count a number of oscillations of the NMOS-based ring oscillator 220 over a predetermined period of time, and output the resulting count value to the processor 1015. To do this, the processor 1015 may reset the oscillator counter 1040, and enable the oscillator counter 1040 at the beginning of the predetermined period of time to start the count. The processor 1015 may then disable the oscillator counter 1040 at the end of the predetermined period of time to stop the count, and read the count value of the oscillator counter 1040.

The count value indicates the frequency of the NMOS-based oscillator 220, and hence the threshold voltage and switching speed of the NMOS transistors in the NMOS-based oscillator 220, as discussed above. The processor 1015 may store the count value in the memory 425 for later use and/or process the count value, as discussed further below. After the measurement, the processor 1015 may disable the NMOS-based oscillator 220 to conserve power by asserting the first enable signal En_N low.

To measure the threshold voltage of PMOS transistors, the processor 1015 may assert the second enable signal En_P low to enable the PMOS-based oscillator 320. The processor 1015 may also command the multiplexer 1030 to couple the output of the PMOS-based oscillator 320 to the counter 1040 using the select signal Sel. The counter 1040 may then count a number of oscillations of the PMOS-based ring oscillator 320 over a predetermined period of time, and output the resulting count value to the processor 1015. To do this, the processor 1015 may reset the oscillator counter 1040, and enable the oscillator counter 1040 at the beginning of the predetermined period of time to start the count. The processor 1015 may then disable the oscillator counter 1040 at the end of the predetermined period of time to stop the count, and read the count value of the oscillator counter 1040.

The count value indicates the frequency of the PMOS-based ring oscillator 320, and hence the threshold voltage and switching speed of the PMOS transistors in the oscillator, as discussed above. The processor 1015 may store the count value in the memory 425 for later use and/or process the count value, as discussed further below. After the measurement, the processor 1015 may disable the PMOS-based oscillator 320 to conserve power by asserting the second enable signal En_P high (which turns off PMOS transistor 370 shown in FIG. 3A).

As discussed above, the processor 1015 may have the counter 1040 count the number of oscillations of the NMOS-based oscillator 220 or the PMOS-based oscillator 320 over a predetermined period of time. To do this, the processor 1015 may track the predetermined period of time using the clock signal (denoted “Clk”) from the clock source 430, as discussed above.

Thus, the process-variation tracking system 1000 provides a count value indicating the frequency of the NMOS-based ring oscillator 220, and hence the threshold voltage and switching speed of the NMOS transistors making up the NMOS-based ring oscillator 220. Similarly, the process-variation tracking system 1000 provides a count value indicating the frequency of the PMOS-based ring oscillator 320, and hence the threshold voltage and switching speed of the PMOS transistors making up the PMOS-based ring oscillator 320.

In the example shown in FIG. 10, the counter 1040 is time-multiplexed between the NMOS-based oscillator 220 and the PMOS-based oscillator 320. This allows the process-variation tracking system 1000 to generate the count values for the NMOS-based oscillator 220 and the PMOS-based oscillator 320 using a single counter. It is to be appreciated that the exemplary system 1000 shown in FIG. 10 may include additional oscillators, in which the output of each of the additional oscillators is coupled to a respective input of the multiplexer 1030. In this example, the processor 1015 may obtain count values for each of the additional oscillators by commanding the multiplexer 1030 to couple the output of each of the additional oscillators to the counter 1040 one at a time, and reading the resulting count value for each of the additional oscillators. Thus, the system 1000 may be scaled up to include additional oscillators.

As discussed above, the count values for the oscillators 220 and 320 may be used to determine whether circuits on the same chip as the tracking system 1000 meet certain timing requirements for proper operation. The count values may also be used to adjust the clock frequency of the clock source 520, adjust the supply voltage of the voltage source 620, and/or adjust the duty cycle of the driver 710 or 770, as discussed above.

In certain aspects, the system 1000 may also include the gating circuit 810 (shown in FIG. 8) coupled between the output of the NMOS-based oscillator 220 and the first input 1032 of the multiplexer 1030, and the gating circuit 910 (shown in FIG. 9) coupled between the output of the PMOS-based oscillator 320 and the second input 1034 of the multiplexer 1030. In these aspects, the processor 1015 may un-gate the NMOS-based oscillator 220 when the NMOS-based oscillator 220 is enabled, and gate the NMOS-based oscillator 220 when the NMOS-based oscillator 220 is disabled. Similarly, the processor 1015 may un-gate the PMOS-based oscillator 320 when the PMOS-based oscillator 320 is enabled, and gate the PMOS-based oscillator 320 when the PMOS-based oscillator 320 is disabled.

In certain aspects, the NMOS-based oscillator 220 and the PMOS-based oscillator 320 may be powered in a power domain controlled by the processor 1015. In this regard, the system 1000 may further include a power switch 1055 (e.g., head switch) configured to control power to the power domain. In the example shown in FIG. 10, the power switch 1055 is implemented with a PMOS transistor 1055, in which the source of the PMOS transistor 1055 is coupled to a first power rail 1050, and the drain of the PMOS transistor 1055 is coupled to a second power rail 1060. The first power rail 1050 is coupled to a power source (not shown). The power source may include a battery, a power management integrated circuit (PMIC), or a combination thereof. The second power rail 1060 is coupled to the NMOS-based oscillator 220 and the PMOS-based oscillator 320, and provides the supply voltage VDD to the oscillators 220 and 320 shown in FIGS. 2A and 3A.

The processor 1015 is configured to output a power control signal (denoted “Power Control”) to the gate of the PMOS transistor 1055 to control whether the power domain is powered on or powered off. To power on the power domain, the processor 1015 asserts the power control signal low, which turns on the PMOS transistor 1055. As a result, the PMOS transistor 1055 couples the first supply rail 1050 (and hence the power source) to the second supply rail 1060, thereby powering the power domain. To power off the power domain, the processor 1015 asserts the power control signal high, which turns off the PMOS transistor 1055. As a result, the PMOS transistor 1055 decouples the first supply rail 1050 (and hence the power source) from the second supply rail 1060, thereby power collapsing the second supply rail 1060.

In certain aspects, the processor 1015 may power on the power domain to obtain count values for the NMOS-based oscillator 220 and the PMOS-based oscillator 320. After the count values are obtained, the processor 1015 may power off the power domain to conserve power.

It is to be appreciated that the multiplexer 1030 and the counter 1040 may also be included in the power domain. In this example, the multiplexer 1030 and the counter 1040 are coupled to the second supply rail 1060 (not shown in FIG. 10), and receive power from the power source via the second supply rail 1060.

Although one PMOS transistor 1055 is shown in FIG. 10 for simplicity, it is to be appreciated that the power switch may be implemented with multiple PMOS transistors coupled in parallel between the first supply rail 1050 and the second supply rail 1060, in which the gates of the multiple PMOS transistor receive the power control signal from the processor 1015.

As discussed above, the processor 1015 may store the count value for the NMOS-based oscillator 220 and the count value for the PMOS-based oscillator 320 in the memory 425. The processor 1015 may determine device settings for one or more devices on the chip based on the count values, and store the device settings in the memory 425, as discussed further below.

For example, the processor 1015 may determine a duty cycle setting for a driver on the chip based on the count value for the NMOS-based oscillator 220 and the count value for the PMOS-based oscillator 320, and store the determined duty cycle setting in the memory 425. For the exemplary driver 710 shown in FIG. 7A, the duty cycle setting may specify which switches 755-1 to 755-n and 765-2 to 765-n in the driver 710 are to be opened and/or closed. For the exemplary driver 770 shown in FIG. 7B, the duty cycle setting may specify the gate bias voltage for the current-starving PMOS transistor 785 and/or the gate bias voltage for the current-starving NMOS transistor 795.

In certain aspects, the processor 1015 may determine the duty cycle setting for a driver (e.g., driver 710 or 770) using a lookup table stored in the memory 425. The lookup table may include different count value ranges for the PMOS-based oscillator 320, and different count value ranges for the NMOS-based oscillator 220. The lookup table may map each one of multiple pairs of count value ranges to a respective device setting, in which each pair of count value ranges includes a respective count value range for the PMOS-based oscillator 320 and a respective count value range for the NMOS-based oscillator 220. A count value range may span one or more count values.

In this example, the processor 1015 may determine which one of the multiple pairs of count value ranges applies to the chip based on the count value for the PMOS-based oscillator 320 and the count value for the NMOS-based oscillator 220 obtained from the counter 1040. To do this, the processor 1015 determines in which one of the count value ranges for the PMOS-based oscillator 320 the count value obtained for the PMOS-based oscillator 320 falls, and in which one of the count value ranges for the NMOS-based oscillator 220 the count value obtained for the NMOS-based oscillator 220 falls. The processor 1015 may then determine the device setting in the lookup table that maps to the determined pair of count value ranges, and store the determined device setting in the memory 425.

For the example in which the device setting includes a duty cycle setting for the driver 710 in FIG. 7A, the switch controller 715 may set the switches 755-1 to 755-n and 765-2 to 765-n in the driver 710 according to the duty cycle setting, as discussed above. For the example in which the device setting includes a duty cycle setting for the driver 770 in FIG. 7B, the bias controller 775 may set the bias voltages of the current-starving transistors 785 and 795 according to the duty cycle setting, as discussed above.

The lookup table discussed above may be generated based on a computer simulation of the chip. For example, the duty cycle setting for each pair of count value ranges in the table may be determined by simulating a driver with PMOS and NMOS transistors corresponding to the pair of count value ranges, applying different duty cycle settings to the driver, and determining which one of the different duty cycle settings results in a duty cycle that is closest to a desired duty cycle (e.g., 50%).

In another example, the lookup table may be generated by performing tests on multiple physical test chips, in which each test chip corresponds to a different pair of count value ranges. In this example, a duty cycle setting may be determined for each test chip by applying different duty cycle settings to a driver on the test chip, and determining which one of the different duty cycle setting results in a duty cycle that is closest to a desired duty cycle (e.g., 50%). The determined duty cycle setting for each test chip may then be entered in the lookup table for the pair of count value ranges corresponding to the chip. In this example, each test chip may include an NMOS-based oscillator 220 and a PMOS-based oscillator 320 for determining which pair of count value ranges corresponds to the test chip, as discussed above.

After the lookup table is generated, the lookup table may be stored in the memory 425. For example, the lookup table may be written to the memory 425 by an external device via the interface 440. The processor 1015 may later access the lookup table to determine the duty cycle setting for a driver on the chip, as discussed above.

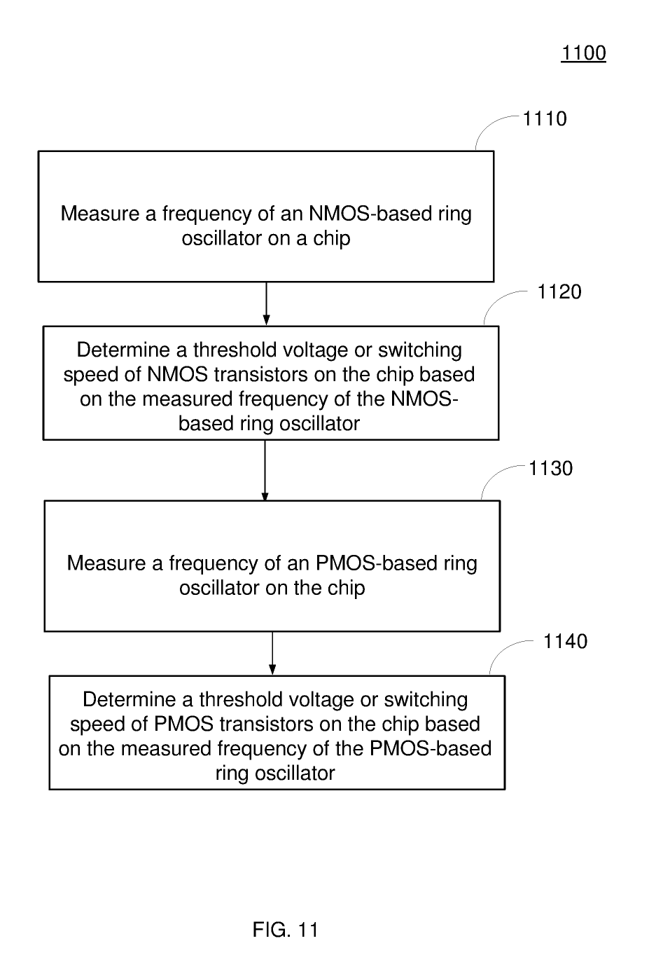

FIG. 11 is a flowchart showing a method 1100 for tracking process variation according to certain aspects of the present disclosure.

At step 1110, a frequency of an NMOS-based ring oscillator on a chip is measured. For example, the frequency of the NMOS-based ring oscillator (e.g., oscillator 220) may be measured by counting a number of oscillations of the oscillator over a period of time.

At step 1120, a threshold voltage or switching speed for NMOS transistors on the chip is determined based on the measured frequency of the NMOS-based ring oscillator. For example, the higher the frequency, the lower the threshold voltage or the higher the switching speed.

At step 1130, a frequency of a PMOS-based ring oscillator on the chip is measured. For example, the frequency of the PMOS-based ring oscillator (e.g., oscillator 320) may be measured by counting a number of oscillations of the oscillator over a period of time.

At step 1140, a threshold voltage or switching speed for PMOS transistors on the chip is determined based on the measured frequency of the PMOS-based ring oscillator. For example, the higher the frequency, the lower the threshold voltage or the higher the switching speed.

It is to be appreciated that, in this disclosure, an NMOS device may refer to an NMOS transistor and a PMOS device may refer to a PMOS transistor.

The processor 415 or 1015 may include general-purpose microprocessors, microcontrollers, digital signal processors (DSPs), field programmable gate array (FPGAs), programmable logic devices (PLDs), controllers, state machines, gated logic, discrete hardware components, dedicated hardware finite state machines, or any combination thereof. The one or more processors may execute instructions stored in one or more memories that cause the one or more processors to perform the operations discussed herein. The one or more memories may be internal to the one or more processors and/or external to the one or more processors. The one or more memories may include any suitable computer-readable media, including RAM, ROM, Flash memory, EEPROM, etc.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A method for tracking process variation, comprising:
measuring a frequency of an NMOS-based ring oscillator on a chip;
determining a threshold voltage or switching speed for NMOS transistors on the chip based on the measured frequency of the NMOS-based ring oscillator;
measuring a frequency of a PMOS-based ring oscillator on the chip; and
determining a threshold voltage or switching speed for PMOS transistors on the chip based on the measured frequency of the PMOS-based ring oscillator.

2. The method of claim 1, wherein the NMOS-based ring oscillator includes a plurality of inverters coupled in a closed loop, each of the inverters comprising:
a first NMOS transistor, wherein the NMOS transistor is diode-connected; and
a second NMOS transistor having a gate coupled to an input of the inverter, and a drain coupled to a source of the first NMOS transistor and an output of the inverter.

3. The method of claim 1, wherein the PMOS-based ring oscillator includes a plurality of inverters coupled in a closed loop, each of the inverters comprising:
a first PMOS transistor, wherein the PMOS transistor is diode-connected; and
a second PMOS transistor having a gate coupled to an input of the inverter, and a drain coupled to a source of the first PMOS transistor and an output of the inverter.

4. The method of claim 1, further comprising adjusting a duty cycle of a driver on the chip based on the determined threshold voltage or switching speed for the NMOS transistors and the determined threshold voltage or switching speed for the PMOS transistors.

5. The method of claim 1, wherein measuring the frequency of the NMOS-based ring oscillator comprises counting a number of oscillations of the NMOS-based ring oscillator over a first period of time, and measuring the frequency of the PMOS-based ring oscillator comprises counting a number of oscillations of the PMOS-based ring oscillator over a second period of time.

6. The method of claim 5, wherein the number of oscillations of the NMOS-based ring oscillator and the number of oscillations of the PMOS-based ring oscillator are counted using a same counter.

7. A method for determining a duty cycle setting for a driver on a chip, comprising:
counting a number of oscillations of an NMOS-based ring oscillator on the chip over a first period of time to obtain a first count value;
counting a number of oscillations of a PMOS-based ring oscillator on the chip over a second period of time to obtain a second count value; and
determining the duty cycle setting for the driver on the chip based on the first count value and the second count value.

8. The method of claim 7, wherein the driver includes a pull-up circuit and a pull-down circuit, the pull-up circuit includes a first plurality of switches, the pull-down circuit includes a second plurality of switches, and the duty cycle setting for the driver specifies which ones of the first and second plurality of the switches are to be closed.

9. The method of claim 7, wherein the driver includes a pull-up circuit and a pull-down circuit, the pull-up circuit includes a first current-starving transistor, the pull-down circuit includes a second current-starving transistor, and the duty cycle setting for the driver specifies at least one of a first gate bias voltage for the first current-starving transistor or a second gate bias voltage for the second current-starving transistor.

10. The method of claim 7, wherein determining the duty cycle setting for the driver comprises looking up the duty cycle setting in a lookup table based on the first count value and the second count value, the lookup table including a plurality of duty cycle settings corresponding to different pairs of count value ranges.

11. The method of claim 7, wherein the NMOS-based ring oscillator includes a plurality of inverters coupled in a closed loop, each of the inverters comprising:
a first NMOS transistor, wherein the NMOS transistor is diode-connected; and
a second NMOS transistor having a gate coupled to an input of the inverter, and a drain coupled to a source of the first NMOS transistor and an output of the inverter.

12. The method of claim 7, wherein the PMOS-based ring oscillator includes a plurality of inverters coupled in a closed loop, each of the inverters comprising:
a first PMOS transistor, wherein the PMOS transistor is diode-connected; and
a second PMOS transistor having a gate coupled to an input of the inverter, and a drain coupled to a source of the first PMOS transistor and an output of the inverter.

13. A process-variation tracking system, comprising:
an NMOS-based ring oscillator;
a PMOS-based ring oscillator; and
at least one counter configured to count a number of oscillations of the NMOS-based oscillator over a first period of time to obtain a first count value, and to count a number of oscillations of the PMOS-based ring oscillator over a second period of time to obtain a second count value.

14. The system of claim 13, wherein the NMOS-based ring oscillator includes a plurality of inverters coupled in a closed loop, each of the inverters comprising:
a first NMOS transistor, wherein the NMOS transistor is diode-connected; and
a second NMOS transistor having a gate coupled to an input of the inverter, and a drain coupled to a source of the first NMOS transistor and an output of the inverter.

15. The system of claim 13, wherein the PMOS-based ring oscillator includes a plurality of inverters coupled in a closed loop, each of the inverters comprising:
a first PMOS transistor, wherein the PMOS transistor is diode-connected; and
a second PMOS transistor having a gate coupled to an input of the inverter, and a drain coupled to a source of the first PMOS transistor and an output of the inverter.

16. The system of claim 13, further comprising a processor coupled to the at least one counter, and configured to determine a duty cycle setting for a driver based on the first count value and the second count value.

17. The system of claim 16, wherein the driver includes a pull-up circuit and a pull-down circuit, the pull-up circuit includes a first plurality of switches, the pull-down circuit includes a second plurality of switches, and the duty cycle setting for the driver specifies which ones of the first and second plurality of the switches are to be closed.

18. The system of claim 16, wherein the driver includes a pull-up circuit and a pull-down circuit, the pull-up circuit includes a first current-starving transistor, the pull-down circuit includes a second current-starving transistor, and the duty cycle setting for the driver specifies at least one of a first gate bias voltage for the first current-starving transistor or a second gate bias voltage for the second current-starving transistor.

19. The system of claim 16, wherein the processor is configured to determine the duty cycle setting by looking up the duty cycle setting in a lookup table based on the first count value and the second count value, the lookup table including a plurality of duty cycle settings corresponding to different pairs of count value ranges.

20. The system of claim 13, further comprising a multiplexer having a first input coupled to the NMOS-based ring oscillator, a second input coupled to the PMOS-based ring oscillator, and an output coupled to the at least one counter, wherein the multiplexer is configured to couple one of the NMOS-based ring oscillator and PMOS-based ring oscillator to the at least one counter at a time.
